(19) United States
(12) Patent Application Publication
(10) Pub. No.: US 2024/0250093 A1
(43) Pub. Date: Jul. 25, 2024

(54) DISPLAY PANEL AND DISPLAY DEVICE

(71) Applicants: Chongqing BOE Optoelectronics Technology Co., Ltd., Chongqing (CN); BOE Technology Group Co., Ltd., Beijing (CN)

(72) Inventors: Bin WAN, Beijing (CN); Xiaoyuan WANG, Beijing (CN); Junhui WU, Beijing (CN); Junming CHEN, Beijing (CN); Guodong YANG, Beijing (CN); Xiaoshuang ZHENG, Beijing (CN); Zhicheng FAN, Beijing (CN)

(21) Appl. No.: 18/561,297

(22) PCT Filed: May 31, 2021
(86) PCT No.: PCT/CN2021/097460

§ 371 Date: Nov. 16, 2023

(51) Int. Cl. H01L 27/12; G02F 1/133; G02F 1/1343; G02F 1/1345; H01L 23/00; H01L 25/16

(52) U.S. Cl. CPC H01L 27/124; G02F 1/13306; G02F 1/134309; G02F 1/1345; H01L 24/05; H01L 24/06; H01L 24/13; H01L 24/14; H01L 24/16; H01L 24/17; H01L 25/167; H01L 2224/05573; H01L 2224/06152; H01L 2224/13082; H01L 2224/14152; H01L 2224/16148; H01L 2224/17517; H01L 2924/1426

(57) ABSTRACT

A display panel includes: a display substrate, including a display region and a peripheral region located outside the display region. The peripheral region includes a bonding region; the display substrate specifically includes a base substrate, a plurality of fanout lines located on one side of the base substrate in the peripheral region and extending to the bonding region, and a plurality of first bonding electrodes electrically connected with the fanout lines in one-to-one correspondence in the bonding region; a drive chip, including a drive chip body and a plurality of pins located on a side of the drive chip body facing the display substrate; wherein the plurality of pins include a plurality of output pins bonded with the first bonding electrodes in one-to-one correspondence.

### CROSS-REFERENCE TO RELATED APPLICATION

This application is a national stage application of PCT Application No. PCT/CN2021/097460, which is filed on May 31, 2021 and entitled “Display Panel and Display Device”, the content of which should be regarded as being incorporated herein by reference.

### TECHNICAL FIELD

Embodiments of the present disclosure relate to the field of display technologies, and particularly to a display panel and a display device.

### BACKGROUND

With development of information technologies, electronic devices are widely used in people's daily life. As one of the most widely used flat panel displays, a liquid crystal display plays an important role in display panels. With continuous upgrading of display products, users' demands for narrow frame display products are getting higher and higher. In order to meet a demand of a narrower frame, left and right bilateral output pins of a drive chip are subsided compared with a middle position. Wiring space of a fanout line is enlarged and a lower edge of a display panel is reduced. However, after the drive chip is bonded, regions on both sides of an output pin in the middle position are not supported, the regions are easy to collapse, which makes the middle position tilt up, which leads to problems of uneven and shallow indentation of a bonding pin in the middle position, which seriously affects reliability of products adversely.

### SUMMARY

An embodiment of the present disclosure provides a display panel, which includes: a display substrate, including a display region and a peripheral region located outside the display region; wherein the peripheral region includes a bonding region; the display substrate specifically includes a base substrate, a plurality of fanout lines located on one side of the base substrate in the peripheral region and extending to the bonding region, and a plurality of first bonding electrodes electrically connected with the fanout lines in one-to-one correspondence in the bonding region; a drive chip, including a drive chip body and a plurality of pins located on a side of the drive chip body facing the display substrate; wherein the plurality of pins include a plurality of output pins bonded with the first bonding electrodes in one-to-one correspondence; a supporting structure located between the drive chip body and the base substrate and in contact with both the drive chip body and the base substrate; wherein an orthographic projection of the supporting structure on the base substrate and an orthographic projection of a fanout line on the base substrate are not overlapped with each other; an orthographic projection of the supporting structure on the drive chip body and an orthographic projection of a pin on the drive chip body are not overlapped with each other.

In some embodiments, the drive chip body includes a first region and a second region located on both sides of the first region; the plurality of input pins include a plurality of first output pins located in the first region and a plurality of second output pins located in the second region; in each first region, a plurality of first output pins are arranged in at least one row of first output pin rows extending along a first direction; in each second region, a plurality of second output pins are arranged into at least one row of second output pin rows; second output pin rows located on both sides of the first region respectively extend along a second direction and a third direction, and the second direction and the third direction are deflected to a side away from the display region relative to the first direction; in each of the second output pin rows, a plurality of second output pins are arranged along the second direction or the third direction and toward the side away from the display region; an orthographic projection of at least part of the supporting structure on the drive chip body falls into the second region.

In some embodiments, the drive chip body further includes: a third region located on one side of the first region; a plurality of pins further include a plurality of input pins located in the third region; an orthographic projection of at least part of the supporting structure on the drive chip body falls into the third region between an input pin and a first output pin.

In some embodiments, a region between an input pin and a first output pin includes a plurality of supporting structure rows; an extension direction of a supporting structure row is the same as that of a first output pin row; supporting structures in two adjacent supporting structure rows are arranged in a dislocation manner in the extension direction of the supporting structure row.

In some embodiments, for each second region, a distance between two adjacent supporting structures close to the first region is greater than a distance between two adjacent supporting structures away from the first region.

In some embodiments, the supporting structure includes: a first supporting layer; an insulation layer located on a side of the first supporting layer facing away from the base substrate; a second supporting layer located on a side of the insulation layer facing away from the first supporting layer.

In some embodiments, the supporting structure further includes a dummy pin located between the drive chip body and the second supporting layer.

In some embodiments, the first supporting layer is disposed in a same layer as a fanout line; the second supporting layer is disposed in a same layer as a first bonding electrode.

In some embodiments, the display region includes: a first conductive layer including a plurality of scan signal lines electrically connected with the fanout lines in one-to-one correspondence; a gate insulation layer located on a side of the scan signal lines facing away from the base substrate; a pixel electrode layer located on a side of the gate insulation layer facing away from the scan signal lines; a second conductive layer located on a side of the pixel electrode layer facing away from the gate insulation layer and including a plurality of data signal lines; a protective layer located on a side of the second conductive layer facing away from the pixel electrode layer; a common electrode layer located on a side of the protective layer facing away from the second conductive layer; the second supporting layer and the first bonding electrode are disposed in a same layer as the common electrode layer, and the insulation layer at least includes the protective layer extending to the peripheral region.

In some embodiments, the fanout lines are disposed in a same layer as the first conductive layer; the insulation layer further includes the gate insulation layer extending to the peripheral region.

In some embodiments, the fanout lines are disposed in a same layer as the second conductive layer; the supporting structure further includes the gate insulation layer extending to the peripheral region.

In some embodiments, the supporting structure includes: an insulation layer; and a dummy pin located between the drive chip body and the insulation layer.

In some embodiments, a distance between an orthographic projection of the supporting structure located in the second region on the drive chip body and an edge of the drive chip body is less than or equal to 200 microns.

In some embodiments, a distance between the supporting structure located in the second region and an adjacent fanout line is greater than or equal to 10 microns.

In some embodiments, the display panel further includes: a plurality of second bonding electrodes, which are located on a same side of the base substrate as the first bonding electrodes in the bonding region; wherein the second bonding electrodes are bonded with the input pins in one-to-one correspondence; a length of a second bonding electrode in an extension direction of a fanout line is greater than a length of an input pin in the extension direction of the fanout line; the length of the second bonding electrode in the extension direction of the fanout line is greater than or equal to 100 microns and less than or equal to 150 microns.

An embodiment of the present disclosure provides a display device, and the display device includes the display panel according to the embodiment of the present disclosure.

### BRIEF DESCRIPTION OF DRAWINGS

In order to describe technical solutions in embodiments of the present disclosure more clearly, drawings needed to be used in the embodiments will be introduced below in brief. Obviously, the drawings described below are only some of the embodiments of the present disclosure, for those skilled in the art, other drawings may be obtained according to these drawings without paying any inventive effort.

FIG. 1 is a schematic diagram of a structure of a display panel according to an embodiment of the present disclosure.

FIG. 2 is a schematic diagram of a structure of a drive chip in a display panel according to an embodiment of the present disclosure.

FIG. 3 is a cross-sectional view along AA′ in FIG. 1 according to an embodiment of the present disclosure.

FIG. 4 is another cross-sectional view along AA′ in FIG. 1 according to an embodiment of the present disclosure.

FIG. 5 is yet another cross-sectional view along AA′ in FIG. 1 according to an embodiment of the present disclosure.

FIG. 6 is a schematic diagram of a structure of another display panel according to an embodiment of the present disclosure.

FIG. 7 is a schematic diagram of a structure of a drive chip in another display panel according to the embodiment of the present disclosure.

FIG. 8 is a schematic diagram of a structure of a drive chip in yet another display panel according to an embodiment of the present disclosure.

FIG. 9 is a schematic diagram of a structure of a drive chip in yet another display panel according to an embodiment of the present disclosure.

FIG. 10 is a schematic diagram of a structure of yet another display panel according to an embodiment of the present disclosure.

FIG. 11 is a schematic diagram of a structure of yet another display panel according to an embodiment of the present disclosure.

### DETAILED DESCRIPTION

In order to make objectives, technical solutions, and advantages of the embodiments of the present disclosure more clear, the technical solutions of the embodiments of the present disclosure will be clearly and completely described below with reference to the drawings of the embodiments of the present disclosure. Apparently, the described embodiments are a part of the embodiments of the present disclosure, not all of the embodiments. Furthermore, without a conflict, embodiments in the present disclosure and features in the embodiments may be combined with each other. Based on the described embodiments of the present disclosure, all other embodiments obtained by those of ordinary skills in the art without inventive effort are within the protection scope of the present disclosure.

Unless otherwise defined, technical terms or scientific terms used in the present disclosure should have the meanings as commonly understood by those of ordinary skill in the art that the present disclosure belongs to. The “first”, “second”, and similar terms used in the present disclosure do not indicate any order, quantity, or importance, but are used only for distinguishing different components. “Include”, “contain”, or similar words mean that elements or objects appearing before the words cover elements or objects listed after the words and their equivalents, but do not exclude other elements or objects. “Connect”, “join”, or a similar term is not limited to a physical or mechanical connection, but may include an electrical connection, whether direct or indirect.

It should be noted that sizes and shapes of various figures in the drawings do not reflect real proportions, and are only for the purpose of schematically illustrating contents of the present disclosure. Moreover, the same or similar elements and the elements having same or similar functions are denoted by same or similar reference numerals throughout the descriptions.

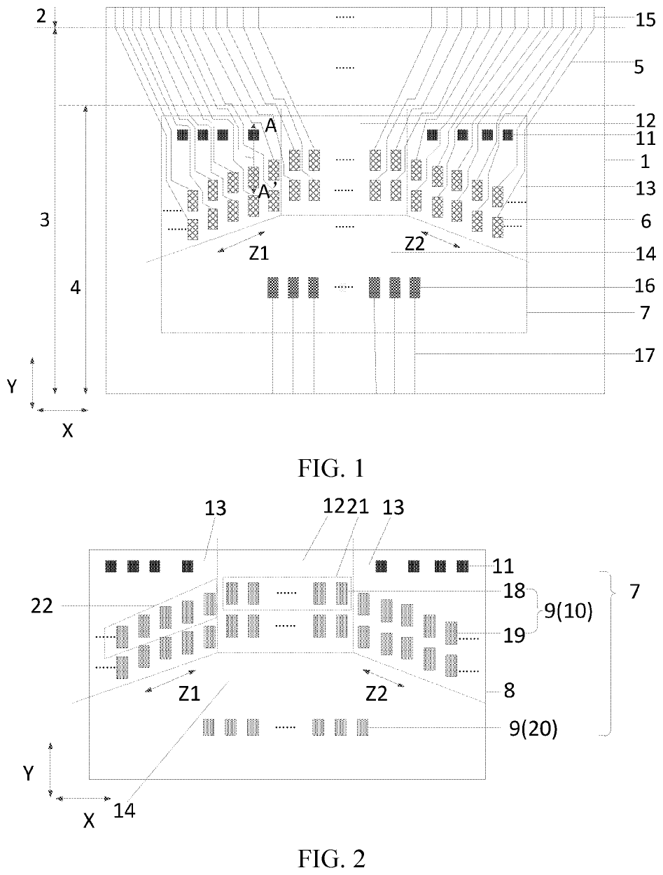

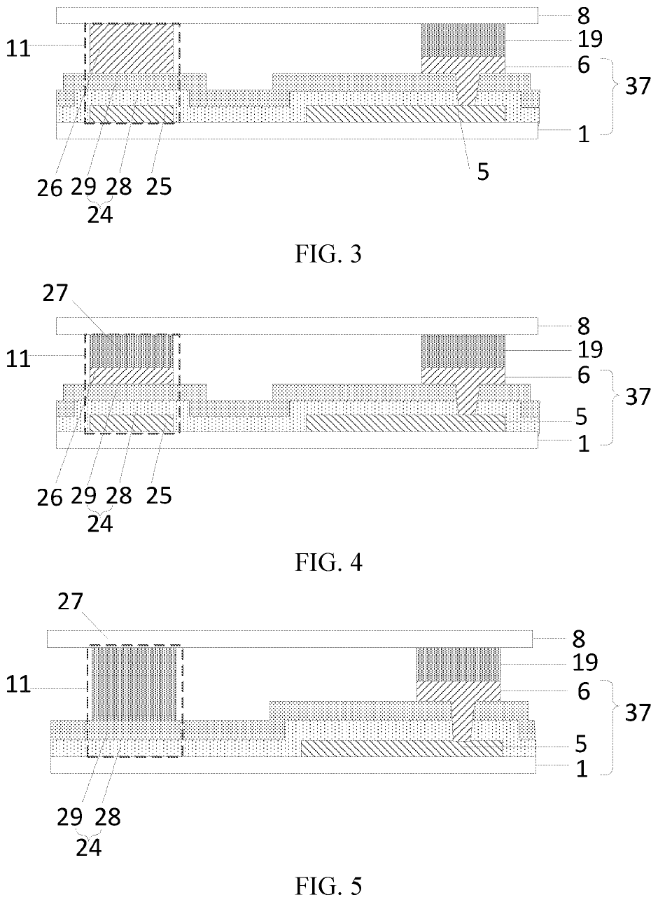

An embodiment of the present disclosure provides a display panel, as shown in FIG. 1, FIG. 2, FIG. 3, FIG. 4, and FIG. 5. The display panel includes: a display substrate 37, which includes a display region 2 and a peripheral region 3 located outside the display region 2; wherein the peripheral region 3 includes a bonding region 4; the display substrate 37 specifically includes: a base substrate 1; a plurality of fanout lines 5 located on one side of the base substrate 1 in the peripheral region 3 and extending to the bonding region 4, and a plurality of first bonding electrodes 6 electrically connected with the fanout lines 5 in the bonding region 4 in one-to-one correspondence; a drive chip 7, which includes a drive chip body 8 and a plurality of pins 9 located on a side of the drive chip body 8 facing the display substrate 37; wherein the plurality of pins 9 include a plurality of output pins 10 bonded with the first bonding electrode 6 in one-to-one correspondence; and a supporting structure 11, which is located between the drive chip body 8 and the base substrate 1 and is in contact with both the drive chip body 8 and the base substrate 1; wherein an orthographic projection of the supporting structure 11 on the base substrate 1 and an orthographic projection of a fanout line 5 on the base substrate 1 are not overlapped with each other; an orthographic projection of the supporting structure 11 on the drive chip body 8 and an orthographic projection of a pin 9 on the drive chip body 8 are not overlapped with each other.

In a display panel according to an embodiment of the present disclosure, a plurality of supporting structures are disposed between a drive chip body and a base substrate, and the supporting structures are in contact with both the drive chip body and the base substrate in a region where no pin is disposed, so that support of the drive chip body and the base substrate may be achieved in a region outside bonding of a pin and a bonding electrode, and a problem that the region outside the bonding of the pin and the bonding electrode is easy to collapse and a problem of uneven indentation and shallow indentation of a bonding pin caused by tilting of some regions of a drive chip may be avoided, thus improving reliability of the display panel and improving a manufacturing yield of the display panel.

It should be noted that only part of a display region is shown in FIG. 1, and only a region covered by a drive chip body is shown by dashed lines, and no pin is shown. FIGS. 3, 4, and 5 may be, for example, cross-sectional views along AA′ in FIG. 1.

In some embodiments, a plurality of fanout lines are arranged along a first direction X.

In some embodiments, as shown in FIGS. 1 and 2, the drive chip body 8 includes a first region 12 and a second region 13 located on both sides of the first region 12; a plurality of input pins 10 include a plurality of first output pins 18 located in the first region 12 and a plurality of second output pins 19 located in the second region 13; in each first region 12, a plurality of first output pins 18 are arranged in at least one row of first output pin rows 21 extending along the first direction X; in each second region 13, a plurality of second output pins 19 are arranged in at least one row of second output pin rows 22; second output pin rows 22 located on both sides of the first region 12 extend along a second direction Z1 and a third direction Z2, respectively, the second direction Z1 and the third direction Z2 intersect with the first direction X, and the second direction Z1 and the third direction Z2 are deflected to a side away from the display region relative to the first direction X; in each second output pin row, a plurality of second output pins are arranged along the second direction Z1 or the third direction Z2 and toward a side away from the display region.

That is, in the display panel according to the embodiment of the present disclosure, compared with the first output pins, second output pins located on both sides of the first region are arranged in a subsided manner to the side away from the display region. Since an output pin is bonded with a first bonding electrode, correspondingly, bonding of first bonding electrodes are also arranged in a subsided manner, so that wiring space of a fanout line may be enlarged, a size of a peripheral region including a bonding region may be reduced, which is beneficial to achieve a narrow frame of the display panel.

In some embodiments, as shown in FIGS. 1 and 2, orthographic projections of at least part of the supporting structures 11 on the drive chip body 8 fall into the second region 13.

In a display panel according to an embodiment of the disclosure, a supporting structure is disposed at least in a second region, thus a problem that an edge of the second region is not supported and easy to collapse due to a subsided arrangement manner adopted for output pins and first bonding electrodes may be avoided, further problems of uneven indentation and shallow indentation of a bonding pin caused by tilting of a first region of a drive chip may be avoided, thereby reliability of the display panel may be improved and a manufacturing yield of the display panel may be improved.

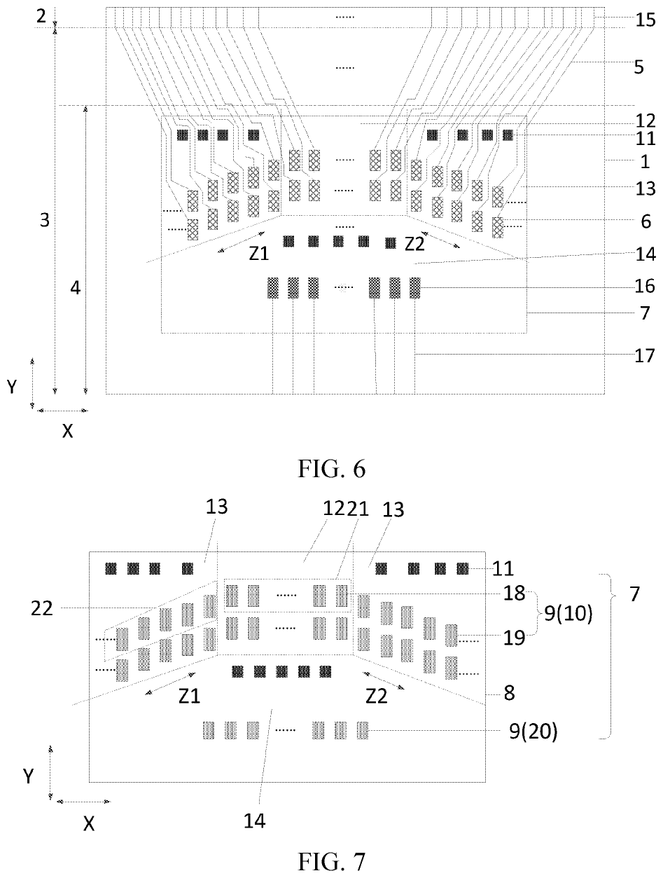

In some embodiments, as shown in FIGS. 6 and 7, the drive chip body 8 further includes: a third region 14 located on one side of the first region 12; the plurality of pins 9 also include a plurality of input pins 20 located in the third region 14; orthographic projections of at least part of the supporting structures 11 on the drive chip body 7 fall into the third region 14 between an input pin 20 and a first output pin 18.

It should be noted that in a related technology, a region between a first output pin and an input pin is unsupported, which is prone to collapse, causing the input pin to tilt and affecting reliability of the display panel adversely.

In a display panel according to an embodiment of the disclosure, a plurality of supporting structures are disposed in a third region between a first output pin and an input pin, so that it may be achieved that a region between the first output pin and the input pin may be supported, a problem that an input pin is tilted may be avoided, a problem of uneven indentation and shallow indentation of a bonding pin may be avoided, thus reliability of the display panel may be improved, and a manufacturing yield of the display panel may be improved.

It should be noted that in FIG. 6 and FIG. 7, a case that the third region 14 between the input pin 20 and the first output pin 18 includes a row of supporting structures 11 is taken as an example for illustration.

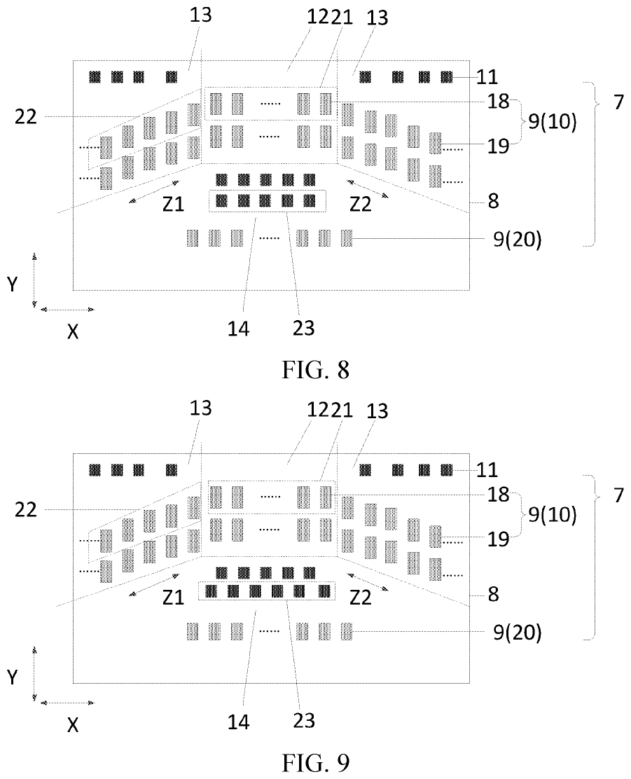

In some embodiments, as shown in FIGS. 8 and 9, it may also be that the third region 14 between first output pins 18 includes a plurality of supporting structure rows 23. So as to further improve a supporting effect between the drive chip body and the base substrate.

In some embodiments, as shown in FIGS. 8 and 9, an extension direction of a supporting structure row 23 is the same as that of a first output pin row 21. That is, the supporting structure row 23 extends along the first direction X.

In some embodiments, as shown in FIG. 9, supporting structures 11 in two adjacent supporting structure rows 23 are arranged in a dislocation manner in an extension direction of the supporting structure rows 23. So as to further improve a supporting effect between the drive chip body and the base substrate.

It should be noted that in FIGS. 8 and 9, a case that the third region includes two supporting structure rows is taken as an example for illustration, and of course, the third region may include more supporting structure rows. In specific implementation, a quantity of supporting structure rows may be set according to an actual size of a region between a first output pin and an input pin.

In some embodiments, as shown in FIG. 1, FIG. 2, FIG. 6, FIG. 7, FIG. 8, and FIG. 9, a plurality of supporting structures 11 corresponding to each second region 13 are arranged in a row along the first direction X.

Therefore, support between the drive chip body and an array substrate may be achieved, and at the same time, excessive reduction of wiring space of a fanout line may be avoided.

In some embodiments, as shown in FIG. 1, FIG. 2, FIG. 6, FIG. 7, FIG. 8, and FIG. 9, a distance between two adjacent supporting structures 11 close to the first region 12 is greater than a distance between two adjacent supporting structures 11 away from the first region 12.

It should be noted that the closer to the first region, the more the quantity of fanout lines. Since setting of a supporting structure needs to avoid a fanout line, it may be set that a distance between two adjacent supporting structures close to the first region is greater than a distance between two adjacent supporting structures far away from the first region.

In specific implementation, a supporting structure may be manufactured, for example, on a base substrate, i.e., the supporting structure is manufactured in a process of manufacturing a display substrate.

In some embodiments, as shown in FIG. 3, the supporting structure 11 includes: a first supporting layer 24; an insulation layer 25 located on a side of the first supporting layer 24 facing away from the base substrate 1; and a second supporting layer 26 located on a side of the insulation layer 25 facing away from the first supporting layer 24.

It should be noted that in FIG. 3, a case that the second supporting layer is in contact with the drive chip body 8 is taken as an example for illustration.

Optionally, in specific implementation, the supporting structure may be manufactured on the drive chip body, for example.

In some embodiments, as shown in FIG. 5, the supporting structure 11 includes: an insulation layer 24; and a dummy pin 27 located between the drive chip body 8 and the insulation layer 24.

Optionally, in specific implementation, the supporting structure may include, for example, a portion manufactured on the base substrate and a portion manufactured on the drive chip body.

In some embodiments, as shown in FIG. 4, the first supporting layer 24, the insulation layer 25, and the second supporting layer 26; the supporting structure 11 further includes a dummy pin 27 located between the drive chip body 8 and the second supporting layer 26.

As shown in FIG. 4, the dummy pin 27 is in contact with both the drive chip body 8 and the second supporting layer 26.

In some embodiments, as shown in FIG. 4, the first supporting layer 25 is disposed in a same layer as a fanout line 5; the second supporting layer 26 is disposed in a same layer as a first bonding electrode 6; the dummy pin 27 is disposed in a same layer as each pin in the drive chip.

That is, a first supporting layer is formed at the same time as a fanout line is formed, a second supporting layer is formed at the same time as a first bonding electrode is formed, and a dummy pin is formed at the same time as a pin is formed when a drive chip is manufactured. In this way, it may be achieved that the drive chip body is supported in a region outside a cathode and a fanout line without increasing a preparation process of the display panel, and a cost may be saved while a pin is prevented from being tilted.

In some embodiments, the display panel according to the embodiment of the present disclosure is a liquid crystal display panel. When the display panel is a liquid crystal display panel, the display panel further includes an opposite substrate disposed opposite to the display substrate and a liquid crystal layer located between the display substrate and the opposite substrate.

Next, taking a case that the display panel is a liquid crystal display panel as an example, each film layer of the display substrate bonded with the drive chip is illustrated as an example.

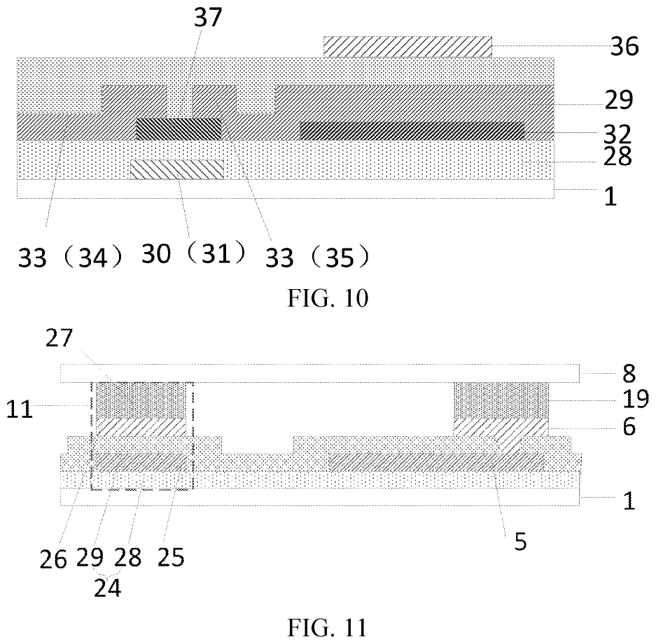

In some embodiments, as shown in FIGS. 1 and 10, the display region 2 includes: a first conductive layer 30 including a plurality of scan signal lines 15 electrically connected with fanout lines 5 in one-to-one correspondence, and a gate electrode 31 of a drive transistor; a gate insulation layer 28 located on a side of a scan signal line 15 facing away from the base substrate 1; a pixel electrode layer 32 located on a side of the gate insulation layer 28 facing away from the first conductive layer 30; a second conductive layer 33 located on a side of the pixel electrode layer 32 facing away from the gate insulation layer 28, including a plurality of data signal lines (not shown) and a source 34 and a drain 35 of the drive transistor; a protective layer 29 located on a side of the second conductive layer 33 facing away from the pixel electrode layer 32; and a common electrode layer 36 located on a side of the protective layer 29 facing away from the second conductive layer 33.

In some embodiments, as shown in FIG. 1, a plurality of scan signal lines 15 are arranged along the first direction X and each scan signal line 15 extends along a fourth direction Y. The first direction X intersects with the fourth direction Y, in FIG. 1, the first direction X is perpendicular to the fourth direction Y. In specific implementation, a plurality of scan signal lines and a plurality of data signal lines are intersected. That is, the plurality of data signal lines are arranged, for example, along the fourth direction Y, and each data signal line extends along the first direction X.

In some embodiments, as shown in FIG. 4, the second supporting layer 26 and the first bonding electrode 6 are disposed in a same layer as the common electrode layer, and the insulation layer 24 includes at least the protective layer 29 extending to the peripheral region.

In some embodiments, as shown in FIG. 4, the first supporting layer 25 and a fanout line 5 are disposed in a same layer as the first conductive layer; the insulation layer 24 further includes the gate insulation layer 28 extending to the peripheral region.

In some embodiments, as shown in FIG. 11, the first supporting layer 25 and a fanout line 5 are disposed in a same layer as the second conductive layer; the supporting structure 11 further includes the gate insulation layer 28 extending to the peripheral region.

Of course, in some embodiments, the display panel according to the embodiment of the present disclosure may also be an electroluminescent display panel. In some embodiments, an electroluminescent display panel specifically includes an active layer, a gate insulation layer, a third conductive layer, an interlayer dielectric layer, a fourth conductive layer, a planarization layer, an anode layer, a pixel definition layer, a light emitting functional layer, and a cathode layer disposed in sequence on a base substrate. The third conductive layer includes, for example, a gate of a transistor and a scan signal line. The fourth conductive layer includes, for example, a source and a drain of the transistor and a data signal line.

In specific implementation, a first supporting layer of a supporting structure and a fanout line may be, for example, disposed in a same layer as a third conductive layer, a second supporting layer of the supporting structure and a first bonding electrode may be, for example, disposed in a same layer as an anode layer, an insulation layer between the first supporting layer and the second supporting layer includes an interlayer dielectric layer, a planarization layer, and the supporting structure further includes a gate insulation layer. Of course, it may also be that a first supporting layer of a supporting structure and a fanout line may be, for example, disposed in a same layer as a fourth conductive layer, a second supporting layer of the supporting structure and a first bonding electrode is disposed in a same layer as an anode layer, an insulation layer between the first supporting layer and the second supporting layer includes a planarization layer, and the supporting structure further includes an interlayer dielectric layer and a gate insulation layer.

In order to further improve a supporting effect of a supporting structure, in some embodiments, a distance between an orthographic projection of a supporting structure located in a second region on the drive chip body and an edge of the drive chip body is less than or equal to 200 microns.

In some embodiments, a distance between the supporting structure located in the second region and an adjacent fanout line is greater than or equal to 10 microns.

In this way, a risk of crushing a fanout line when the drive chip is bonded may be avoided, and a yield of the display panel may be ensured.

In some embodiments, as shown in FIGS. 1 and 6, the display panel further includes: a plurality of second bonding electrodes 16 located on a same side of the base substrate 1 as the first bonding electrodes 6 in the bonding region 4; the second bonding electrodes 16 are bonded with the input pins in one-to-one correspondence.

In some embodiments, a length of a second bonding electrode in an extension direction of a fanout line is greater than a length of an input pin in the extension direction of the fanout line, and the length of the second bonding electrode in the extension direction of the fanout line is greater than or equal to 100 microns and less than or equal to 150 microns.

That is, the display panel according to the embodiment of the present disclosure is equivalent to increasing a length of a second bonding electrode in the fourth direction, which may further improve a supporting effect between the drive chip body and the base substrate.

In some embodiments, a second bonding electrode is disposed in a same layer as a first bonding electrode.

In some embodiments, as shown in FIGS. 1 and 6, the display panel further includes a connection lead 17. In specific implementation, the connection lead is electrically connected with a flexible circuit board, so that the flexible circuit board may be used for providing a signal to the drive chip.

In some embodiments, the connection lead is disposed in a same layer as a fanout line.

An embodiment of the present disclosure provides a display device, and the display device includes the display panel according to the embodiment of the present disclosure.

The display device according to the embodiment of the present disclosure is any product or component with a display function, such as a mobile phone, a tablet computer, a television, a display, a laptop computer, a digital photo frame, or a navigator. Other essential components included in the display device which should be understood to be included in the display device by those of ordinary skill in the art will not be described repeatedly herein, and should not be taken as a limitation on the present disclosure. Implementation of the display device may be referred to the embodiment of the display panel described above and repetition will not be repeated here.

To sum up, for the display panel and the display device according to the embodiments of the present disclosure, a plurality of supporting structures are disposed between the drive chip body and the base substrate, and the supporting structures are in contact with both the drive chip body and the base substrate in a region where no pin is disposed, so that supporting of the drive chip body and the base substrate may be achieved in a region other than bonding of a pin and a bonding electrode, a problem that the region other than the bonding of the pin and the bonding electrode is prone to collapse may be avoided, and a problem of uneven indentation and shallow indentation of a bonding pin caused by tilting of some regions of the drive chip may be avoided, thereby improving reliability of the display panel and improving a manufacturing yield of the display panel. Although preferred embodiments of the present invention have been described, those skilled in the art may make additional changes and modifications to these embodiments once underlying inventive concepts are known. Therefore, appended claims are intended to be interpreted to encompass preferred embodiments as well as all changes and modifications falling within the scope of the present invention.

Apparently, various modifications and variations to the embodiments of the present invention may be made by those skilled in the art without departing from the spirit and scope of the embodiments of the present invention. Thus, if these modifications and variations to the embodiments of the present invention fall within the scope of the claims of the present invention and their equivalent techniques, the present invention is intended to include these modifications and variations.

1. A display panel, wherein the display panel comprises:
a display substrate, comprising a display region and a peripheral region located outside the display region; wherein the peripheral region comprises a bonding region; the display substrate specifically comprises: a base substrate, a plurality of fanout lines which are located on one side of the base substrate in the peripheral region and extend to the bonding region, and a plurality of first bonding electrodes which are electrically connected with the fanout lines in one-to-one correspondence in the bonding region;
a drive chip, comprising a drive chip body and a plurality of pins located on one side of the drive chip body facing the display substrate; wherein the plurality of the pins comprise a plurality of output pins bonded with the first bonding electrodes in one-to-one correspondence;
a supporting structure located between the drive chip body and the base substrate and in contact with both the drive chip body and the base substrate; wherein an orthographic projection of the supporting structure on the base substrate and an orthographic projection of a fanout line on the base substrate are not overlapped with each other; an orthographic projection of the supporting structure on the drive chip body and an orthographic projection of a pin on the drive chip body are not overlapped with each other.

2. The display panel according to claim 1, wherein the drive chip body comprises: a first region and a second region located on both sides of the first region;
the plurality of input pins comprise a plurality of first output pins located in the first region and a plurality of second output pins located in the second region;
in each first region, a plurality of the first output pins are arranged in at least one row of first output pin rows extending along a first direction; in each second region, a plurality of the second output pins are arranged into at least one row of second output pin rows; the second output pin rows located on both sides of the first region respectively extend along a second direction and a third direction, and the second direction and the third direction are deflected to a side away from the display region relative to the first direction; in each of the second output pin rows, a plurality of the second output pins are arranged along the second direction or the third direction and toward the side away from the display region;
an orthographic projection of at least part of the supporting structure on the drive chip body falls into the second region.

3. The display panel according to claim 1, wherein the drive chip body further comprises: a third region located on one side of the first region;
a plurality of the pins further comprise a plurality of input pins located in the third region;
an orthographic projection of at least part of the supporting structure on the drive chip body falls into the third region between an input pin and a first output pin.

4. The display panel according to claim 3, wherein a region between the input pin and the first output pin comprises a plurality of supporting structure rows; an extension direction of a supporting structure row is the same as that of a first output pin row;
supporting structures in two adjacent supporting structure rows are arranged in a dislocation manner in the extension direction of the supporting structure row.

5. The display panel according to claim 2,
wherein for each second region, a distance between two adjacent supporting structures close to the first region is greater than a distance between two adjacent supporting structures away from the first region.

6. The display panel according to claim 1, wherein the supporting structure comprises:
a first supporting layer;
an insulation layer located on a side of the first supporting layer facing away from the base substrate;
a second supporting layer located on a side of the insulation layer facing away from the first supporting layer.

7. The display panel according to claim 6, wherein the supporting structure further comprises: a dummy pin located between the drive chip body and the second supporting layer.

8. The display panel according to claim 6, wherein the first supporting layer is disposed in a same layer as a fanout line; the second supporting layer is disposed in a same layer as a first bonding electrode.

9. The display panel according to claim 8, wherein the display region comprises:
a first conductive layer comprising a plurality of scan signal lines electrically connected with the fanout lines in one-to-one correspondence;
a gate insulation layer located on a side of the scan signal lines facing away from the base substrate;
a pixel electrode layer located on a side of the gate insulation layer facing away from the scan signal lines;
a second conductive layer located on a side of the pixel electrode layer facing away from the gate insulation layer and comprising a plurality of data signal lines;
a protective layer located on a side of the second conductive layer facing away from the pixel electrode layer;
a common electrode layer located on a side of the protective layer facing away from the second conductive layer;
the second supporting layer and the first bonding electrode are disposed in a same layer as the common electrode layer, and the insulation layer at least comprises the protective layer extending to the peripheral region.

10. The display panel according to claim 9, wherein the fanout lines are disposed in a same layer as the first conductive layer; the insulation layer further comprises the gate insulation layer extending to the peripheral region.

11. The display panel according to claim 9, wherein the fanout lines are disposed in a same layer as the second conductive layer; the supporting structure further comprises the gate insulation layer extending to the peripheral region.

12. The display panel according to claim 1, wherein the supporting structure comprises:
an insulation layer; and
a dummy pin located between the drive chip body and the insulation layer.

13. The display panel according to claim 2, wherein a distance between an orthographic projection of the supporting structure located in the second region on the drive chip body and an edge of the drive chip body is less than or equal to 200 microns.

14. The display panel according to claim 2, wherein a distance between the supporting structure located in the second region and an adjacent fanout line is greater than or equal to 10 microns.

15. The display panel according to claim 3, wherein the display panel further comprises:
a plurality of second bonding electrodes, which are located on a same side of the base substrate as the first bonding electrodes in the bonding region; wherein the second bonding electrodes are bonded with the input pins in one-to-one correspondence;
a length of a second bonding electrode in an extension direction of a fanout line is larger than a length of an input pin in the extension direction of the fanout line; the length of the second bonding electrode in the extension direction of the fanout line is greater than or equal to 100 microns and less than or equal to 150 microns.

16. A display device, wherein the display device comprises a display panel according to claim 1.
